(19) United States
(12) Patent Application Publication
(10) Pub. No.: US 2019/0173417 A1
(43) Pub. Date: Jun. 6, 2019

(54) MULTIFUNCTIONAL SOLAR PANEL

(71) Applicant: Zorica Dulovic, Belgrade (RS)

(72) Inventor: Zorica Dulovic, Belgrade (RS)

(21) Appl. No.: 16/324,696

(22) PCT Filed: May 9, 2017
(86) PCT No.: PCT/RS2017/000005

§ 371 Date: Feb. 11, 2019

(30) Foreign Application Priority Data
Sep. 2, 2016 (RS) P-2016/0731

(51) Int. Cl. H02S 20/26; H01L 31/048; H02S 40/38

(52) U.S. Cl. CPC H02S 20/26; H02S 40/38; H01L 31/0481

(57) ABSTRACT

A multifunctional solar panel (S) performed of housing (15) of transparent material whose external surface is protected by layer of nano-technological material. Housing (15) (looking in transversal section) is performed in form of trapezium, with slope of upper base of trapezium made under angle α compared to horizontal line, for draining water from roadway. Upper surface of housing (15) is performed with parallel recesses (151) that are placed transversally compared to direction of movement of vehicles. Under upper surface, inside housing (15), is placed transparent heating body (10), solar panel (1) and piezoelectrical board (13). All indicated elements are placed one under the other, while under all is placed housing (152) of central directing unit (5) with accompanying electronic and electrical elements. In face of multifunctional solar panel (S), at width of highway, is placed another multifunctional solar panel (S) performed with counterslope towards right embankment of highway.

### FIELD OF TECHNIQUE

The invention refers to the field of electrical engineering, i.e. semiconducting technique, more precisely field of photoelectricity, i.e. field of devices for transforming energy of light into electrical energy.

According to the International Classification of Patents (ICP 2015.01) the invention is classified in Class H 01 L 31/04 by which are defined semiconducting devices sensitive to infrared radiation, light, electromagnetic radiation of shorter wavelengths or corpuscular radiation, specially adapted as devices for photoelectrical transformation, i.e. for transformation of energy of such radiation into electrical energy.

### TECHNICAL PROBLEM

The technical problem resolved by this invention consists in the following: how to constructively solve multifunctional solar panel, that would be used as driving surface on highways so that by application of housings from transparent material, transparent heating body, solar panel and piezoelectric board, placed one under the other and central directing unit with accompanying electronics, all placed in a special housing under panel, in order to enable light and solar energy and mechanical energy of pressure into electrical energy, by which may be charged batteries, supplied inductors and other consumers contained in multifunctional solar panel, while excess of electrical energy would be returned into system of public procurement of electrical energy.

### STATE OF TECHNIQUE

The applicant has no knowledge of solutions similar to multifunctional solar panel, as the solution described in this patent application.

### EXPOSITION OF ESSENCE OF THE INVENTION

The technical problem is successfully solved by the multifunctional solar panel that is used as driving surface on highways. The multifunctional solar panel, according to this invention, is performed of housing of transparent material, whose exterior surface in protected by a layer of nano-technological material. Under upper surface, inside housing, is placed transparent heating body, solar panel and piezoelectric board. All indicated elements are place one under the other and under it all is placed housing of central directing unit with accompanying electronic and electrical elements. Inside this housing are placed also electrically connected internal battery, current converters and circuit breakers which distribute electrical energy to consumers, to batteries (internal and external) or to distributing network of alternating current. Such described electrical energy is directed by central directing unit which, by receiver-sender with antenna, is connected to central dispatching center. Some elements are placed out of housing, such as for example temperature device, external inductor, external battery and receiver-sender with antenna.

Advantages of such solution of multifunctional solar panel are that thanks to solar panel is enabled transformation of solar energy into electrical, at an extremely big surface. Thanks to piezoelectric board is enabled transformation of impulses of force of pressure, due to movement of vehicles, into electrical energy. Produced electrical energy is used for own necessities of users in panel, while excess of energy for filling batteries by direct current, inductive supply of electromobiles that circulate on road or return of alternating current into public distrubutive system of electrical energy.

### SHORT DESCRIPTION OF FIGURES OF THE DRAWING

The invention is described in detail by enclosed drawings in which:

FIG. 1 shows multifunctional solar panel S built in a highway;

FIG. 2 shows axonometric appearence of multifunctional solar panel;

FIG. 3 shows section “A-A” from FIG. 1;

FIG. 4 shows block scheme of mechanical and electrical connections of panel:

FIG. 5 shows detail “A” from FIG. 1, according to variant I.

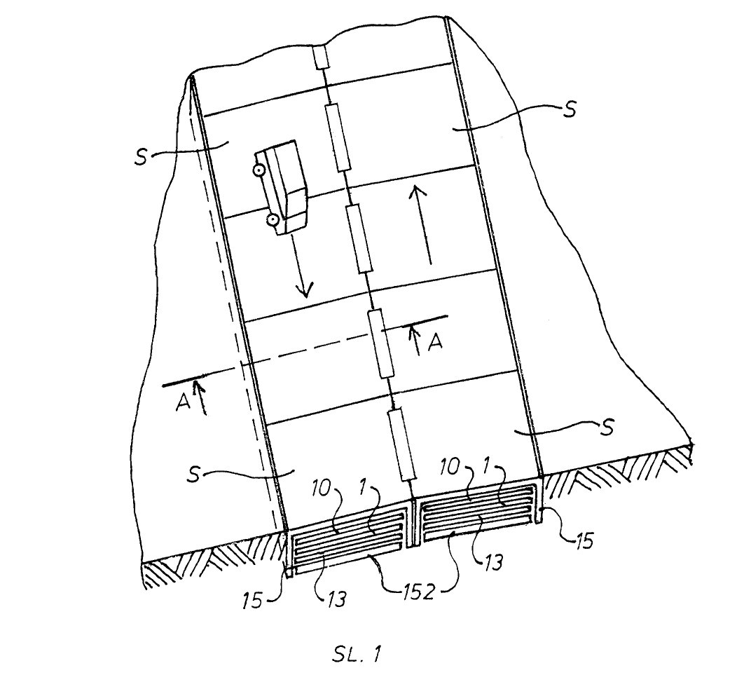

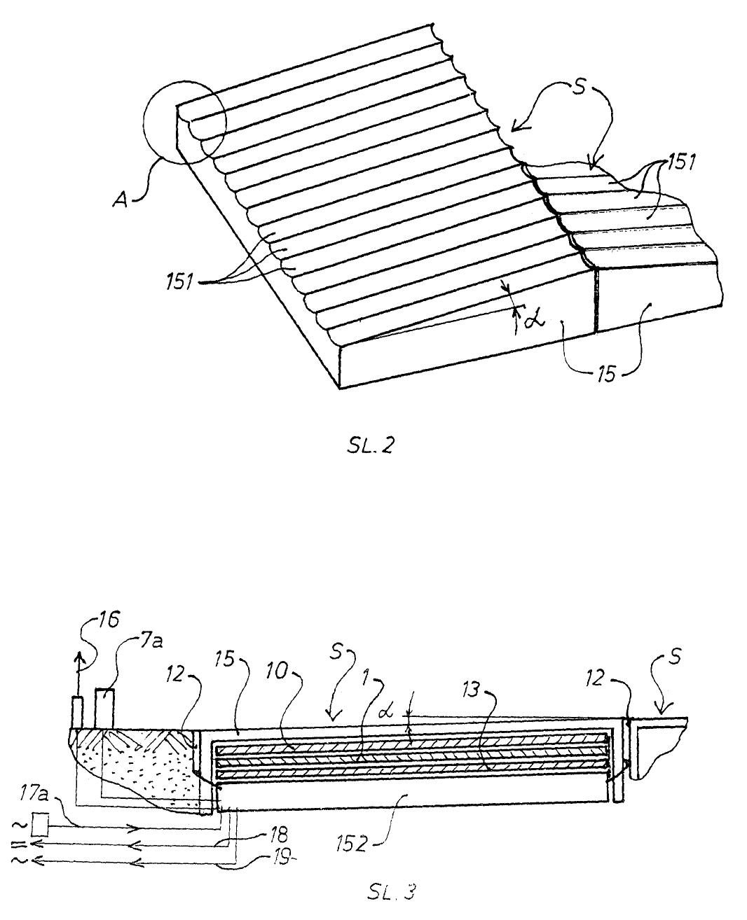

### DETAILED DESCRIPTION OF THE INVENTION

Multifunctional solar panel S, according to basic variant of performance, derived from housing 15 of transparent material, whose exterior surface in protected by layer of nano-technological material. Housing 15 (looking in transversal section) is performed in form of trapezium, with slope of upper base of trapezium made under angle α compared to horizontal line, for draining water from roadway. Upper surface of housing 15 is performed with parallel recesses 151, for draining water from roadway. Recesses 151 are placed transversally compared to direction of movement of vehicles. Under upper surface, inside housing 15, is placed transparent heating body 10, solar panel 1 and piezoelectrical board 13. All indicated elements are placed one under the other, while under all is placed housing 152 of central directing unit 5 with accompanying electronic and electrical elements. Left and right of panel S, out of housing 15, looking in transversal section, are placed temperature devices 12 electrically connected with central directing unit 5. Out of housing 15, on embankment of highway, are placed external inductor 7a and antenna 16 of sender-receiver which are electrically connected with central directing unit 5. With it are connected and through earth performed also external source 17a of alternating current, drain 18 of direct current into public network, as well as drain 19 of alternating current into public distribution network. In face of multifunctional solar panel S, at width of highway, is placed another multifunctional solar panel S with counterslope towards right embankment of highway (looking in transversal section as picture in mirror).

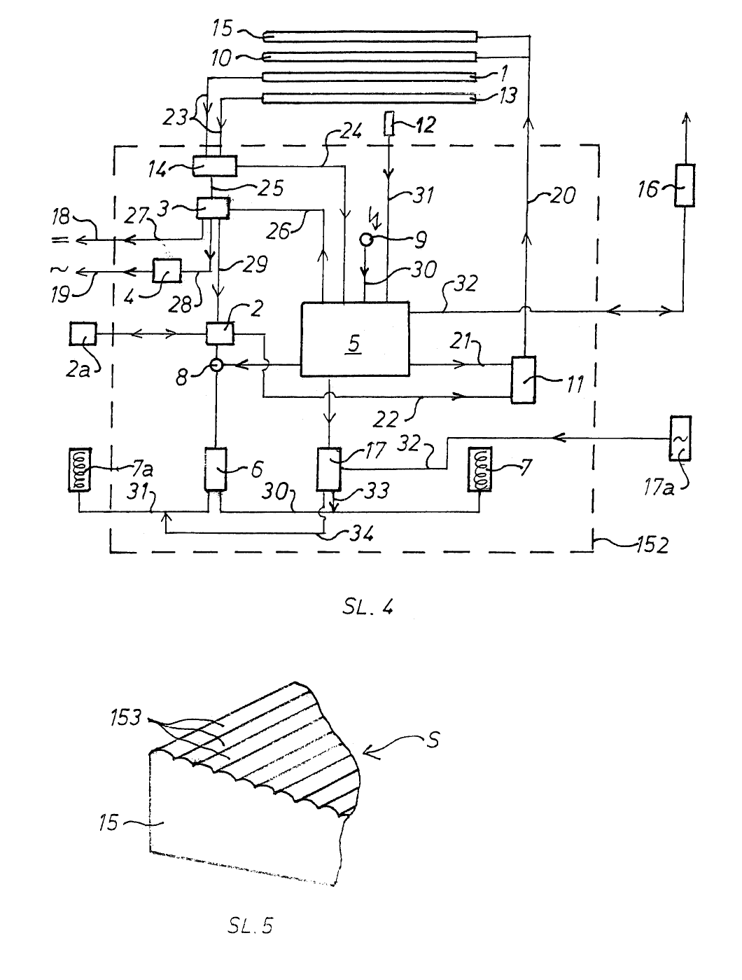

Electrical connections of elements of multifunctional solar panel S are performed in following way (FIG. 4). Housing 15 and heating body 10 are connected by electroconductor 20 with circuit breaker 11 which is connected by conductor 21 to central directing unit 5, and by conductor 22 with battery 2. Battery 2 is directly connected with external battery 2a. Solar panel 1 and piezoelectric board 13 by conductors 23 are connected with attaching place 14 which is connected by conductor 24 to central directing unit 5 and by conductor 25 to circuit breaker 3. Circuit breaker 3 is connected by conductor 26 to central directing unit 5, by conductor 27 with external exit 18 of direct current, by conductor 28, through current convector 4, with external exit 19 of alternating current. Circuit breaker 3 is connected by conductor 29 to battery 2. Central directing unit 5 is connected by conductor 30 to receiver 9, by conductor 31 to temperature device and by conductor 32 to antenna 16 of receiver-sender. Central directing unit 5 and battery 2 are connected directly with circuit breaker 8 which is linked to current converter 6. Current converter 6 is connected by conductor 30 to inductor 7 and by conductor 31 to external inductor 7a. Central directing unit 5 is connected with circuit breaker 17 which is connected by conductor 32 to external source 17a of alternating current, while by conductor 33 it is connected to conductor 30 and by conductor 34 to conductor 31.

Multifunctional solar panel S, according to variant I of performance, is performed entirely according to basic variant, only that upper surface of housing 15 is performed with parallel bumps 153, that enables drainage of water from roadway. Bumps 153 are placed transversally related to direction of vehicle movement.

### Methods of Industrial or Other Application of the Invention

Multifunctional solar panel S represents a device that enables transformation of solar and mechanical energy into electrical. Electrical energy charges internal battery 2 or external battery 2a. Batterys serve for maintenance of constant electrical energy. By produced energy are supplied users of multifunctional solar panel S, such as heating body 10, that prevents freezing of driving surface of panel at low temperatures, and housing 15 if it has integrated heaters. To this function also contributes temperature device 12 of external surface of roadway, that is teamed with central directing unit 5. Housing 15 protects mechanically sensitive systems under itself and passes through specter of solar radiation necessary for stiring up solar panel 1. Upper surface (driving layer) of housing is nano-technologically configurated to eliminate dirt, while recess 151 or bump 153, apart from drainage of rain, enables a greater force of friction with vehicle pneumatics. Apart from this, serious consumers of electrical energy are also inductors 7, 7a that serve for wireless supply of vehicles with electrical energy. Vehicles that pass over or by inductors 7, 7a shall be permitted to consume inducted electrical energy according to instructions from external operational center, by central directing unit 5, according to system of prepayed or postpayed users, as with mobile telephones. Surplus of produced electrical energy is directed to charging batteries or for external direct or alterating network of public distribution of electrical energy. In every case, about distribution and way of use of produced electrical energy “decide” external operational center and central directing unit 5, that are in constant communication and coordination of parameters, by antenna 16 of receiver-sender. In every case, by external operational center and wireless connection with central directing unit 5 is always possible change of regime of work of multifunctional solar panel S. If necessary, for supply of multifunctional solar panel S one can always use current from public distribution network.

1. Multifunctional solar panel S, according to basic variant of performance, characterised in that housing (15) of transparent material, performed in form of trapezium, with slope of upper base of trapezium is made under angle α compared to horizontal line, whose upper surface is performed with parallel recesses (151) and protected by layer of nano-technological material, that recesses (151) are placed transversally compared to direction of movement of vehicles, that under upper surface, inside housing (15), are placed transparent heating body (10), solar panel (1) and piezoelectrical board (13), one under the other, while under all is placed housing (152) of central directing unit (5) with accompanying electronic and electrical elements, that left and right from panel (S), out of housing (15), are placed temperature devices (12) electrically connected with central directing unit (5) and, on embankment of highway, are placed external inductor (7a) and antenna (16) of sender-receiver electrically connected with directing unit (5), with which are connected and through earth performed also external source (17a) of alternating current, drain (18) of direct current, as well as drain (19) of alternating current, while in face of multifunctional solar panel (S), at width of highway, is placed another multifunctional solar panel (S) performed with counterslope towards right embankment of highway.

2. Multifunctional solar panel (S), according to claim 1 and basic variant of performance, characterised in that housing (15) and heating body (10) are connected by electroconductor (20) with circuit breaker (11) which is connected by conductor (21) to central directing unit (5), and by conductor (22) with battery (2) which is directly connected with external battery (2a), that solar panel (1) and piezoelectric board (13) by conductors (23) are connected with attaching place (14) which is connected by conductor (24) to central directing unit (5) and by conductor (25) with circuit breaker (3) which is connected by conductor (26) to central directing unit (5), by conductor (27) with external exit (18) of direct current, by conductor (28), through current convector (4), with external exit (19) of alternating current, by conductor (29) connected to battery (2), that central directing unit (5) is connected by conductor (30) to receiver (9), by conductor (31) to temperature device and by conductor (32) to antenna (16) of sender-receiver, that central directing unit (5) and battery (2) are connected directly with circuit breaker (8) which is linked to current converter (6) and he is connected by conductor (30) to inductor (7), by conductor (31) to external inductor (7a), while central directing unit (5) is connected with circuit breaker (17) which is connected by conductor (32) to external source (17a) of alternating current, while by conductor (33) is connected to conductor (30) and by conductor (34) to conductor (31).

3. Multifunctional solar panel (S), according to claim 1 and variant I of performance, characterised in that multifunctional solar panel (S) is performed entirely according to basic variant, only that upper surface of housing (15) is performed with parallel bumps (153) which are placed transversally related to direction of vehicle movement.
